(19) United States
(12) Patent Application Publication
(10) Pub. No.: US 2025/0356916 A1
(43) Pub. Date: Nov. 20, 2025

(54) MEMORY CELL, MEMORY ARRAY, ELECTRONIC DEVICE AND DATA PROCESSING METHOD

(71) Applicant: PEKING UNIVERSITY, Beijing (CN)

(72) Inventors: Zongwei WANG, Beijing (CN); Yimao CAI, Beijing (CN); Yuhang YANG, Beijing (CN)

(73) Assignee: PEKING UNIVERSITY, Beijing (CN)

(21) Appl. No.: 19/207,904

(22) Filed: May 14, 2025

(30) Foreign Application Priority Data
May 15, 2024 (CN) 202410605219.8

(51) Int. Cl. G11C 13/00

(52) U.S. Cl. CPC G11C 13/0069; G11C 13/0028; G11C 13/0038; G11C 13/004; G11C 13/0097

(57) ABSTRACT

The present disclosure relates to a memory cell, a memory array, an electronic device and a data processing method. The memory cell includes a first transistor and a second transistor. A first terminal of the first transistor is configured to be electrically connected to a first bit line through a first memory device, a second terminal of the first transistor is configured to be electrically connected to a source line, and a control terminal of the first transistor is configured to be electrically connected to a first word line. A first terminal of the second transistor is configured to be electrically connected to a second bit line through a second memory device, a second terminal of the second transistor is configured to be electrically connected to the first terminal of the first transistor, a control terminal of the second transistor is configured to be electrically connected to a second word line, and a substrate of the second transistor is configured to be electrically connected to a substrate of the first transistor and a write source line.

### CROSS-REFERENCE TO RELATED APPLICATIONS

The present disclosure claims priority to Chinese patent application No. 2024106052198, titled “MEMORY CELL, MEMORY ARRAY, ELECTRONIC DEVICE AND DATA PROCESSING METHOD”, filed on May 15, 2024, the entire content of which is incorporated herein by reference.

### TECHNICAL FIELD

The present disclosure relates to the field of integrated circuit technologies, and in particular, to a memory cell, a memory array, an electronic device and a data processing method.

### BACKGROUND

With the development of data storage technology and the popularization of storage chips in the fields of big data, Internet of Things, dedicated hardware, cloud computing and other fields, the market demand for the storage density and performance of non-transitory memory is constantly increasing.

### SUMMARY

In a first aspect, the present disclosure provides a memory cell, including a first transistor and a second transistor. A first terminal of the first transistor is configured to be electrically connected to a first bit line through a first memory device, a second terminal of the first transistor is configured to be electrically connected to a source line, and a control terminal of the first transistor is configured to be electrically connected to a first word line. A first terminal of the second transistor is configured to be electrically connected to a second bit line through a second memory device, a second terminal of the second transistor is configured to be electrically connected to the first terminal of the first transistor, a control terminal of the second transistor is configured to be electrically connected to a second word line, and a substrate of the second transistor is electrically connected to a substrate of the first transistor and is configured to be electrically connected a write source line.

In some embodiments, the first memory device and the second memory device each have at least two variable memory states.

In some embodiments, the first memory device is selected from the group consisting of a resistive random-access memory, a phase change memory, and any combination thereof.

In some embodiments, the second memory device is selected from the group consisting of a resistive random-access memory, a phase change memory, and any combination thereof.

In some embodiments, the first transistor and the second transistor are each a metal-oxide-semiconductor field-effect transistor.

In some embodiments, the memory cell is configured to:
during an erase/reset state: provide a write first data signal to the write source line, and connect the first bit line and the second bit line to a ground terminal, such that a parasitic PN junction in the substrate of the first transistor and a parasitic PN junction in the substrate of the second transistor are turned on to write first data to the first memory device and the second memory device; and
during a write state: apply a turn-on voltage to the first word line to turn on the first transistor, provide a write second data signal to the first bit line, and write second data to the first memory device; and/or, apply a turn-on voltage to the second word line to turn on the second transistor, provide a write second data signal to the second bit line, and write second data to the second memory device.

In some embodiments, the memory cell is configured to:
during a read state: apply a turn-on voltage to the first word line to turn on the first transistor, and read data stored in the first memory device through the first bit line; and/or
apply a turn-on voltage to the second word line to turn on the second transistor, and read data stored in the second memory device through the second bit line.

In a second aspect, the present disclosure further provides a memory array, including a plurality of memory areas arranged in a row-column matrix. Each memory area includes a plurality of memory cells described in any one of the above embodiments. The plurality of memory cells are arranged in a row-column matrix. The memory cells of each memory area are configured as follows: first bit lines of memory cells in a same row are all connected to a same first common bit line, second bit lines of the memory cells in the same row are all connected to a same second common bit line, first bit lines of memory cells in different rows are connected to different first common bit lines, respectively, and second bit lines of the memory cells in different rows are connected to different second common bit lines, respectively;
control terminals of first transistors of memory cells in a same column are all connected to a same first common word line, and control terminals of first transistors of memory cells in different columns are connected to different first common word lines, respectively; control terminals of second transistors of the memory cells in the same column are all connected to a same second common word line, and control terminals of second transistors of the memory cells in different columns are connected to different second common word lines, respectively; and
substrates of all transistors of memory cells in a same memory area are all electrically connected to a same common write source line, and memory cells in different memory areas are connected to different common write source lines, respectively.

In a third aspect, the present disclosure further provides an electronic device, including: the memory cell in any one of the above embodiments, or the memory array in any one of the above embodiments.

In a fourth aspect, the present disclosure further provides a data processing method for performing data processing on the memory cell in any one of the above embodiments. The data processing method includes at least one of the following steps:
during an erase/reset state: providing a write first data signal to the write source line, and connecting the first bit line and the second bit line to a ground terminal, such that a parasitic PN junction in the substrate of the first transistor and a parasitic PN junction in the substrate of the second transistor are forward biased to write first data to the first memory device and the second memory device;
during a write state: applying a turn-on voltage to the first word line to turn on the first transistor, providing a write second data signal to the first bit line, and writing second data to the first memory device, and/or applying a turn-on voltage to the second word line to turn on the second transistor, providing a write second data signal to the second bit line, and writing second data to the second memory device; and
during a read state: applying a turn-on voltage to the first word line to turn on the first transistor, and reading data stored in the first memory device through the first bit line; and/or applying a turn-on voltage to the second word line to turn on the second transistor, and reading data stored in the second memory device through the second bit line.

In a fifth aspect, the present disclosure further provides a data processing method for performing data processing on the memory array in any one of the above embodiments. The data processing method includes at least one of the following steps:
during an erase/reset state: providing a write first data signal to a common write source line of a selected memory area, and connecting a first common bit line and a second common bit line to a ground terminal, such that a parasitic PN junction in a substrate of a first transistor and a parasitic PN junction in a substrate of a second transistor of the selected memory area are forward biased to write first data to a first memory device and a second memory device of the selected memory area;
during a write state: applying a turn-on voltage to a first common word line of the selected memory area to turn on the first transistor of the selected memory area, providing a write second data signal to the first common bit line of the selected memory area, and writing second data to the first memory device of the selected memory area; and/or, applying a turn-on voltage to a second common word line of the selected memory area to turn on the second transistor of the selected memory area, providing a write second data signal to the second common bit line of the selected memory area, and writing second data to the second memory device of the selected memory area; and
during a read state: applying a turn-on voltage to the first common word line of the selected memory area to turn on the first transistor of the selected memory area, and reading data stored in the first memory device through the first common bit line of the selected memory area; and/or, applying a turn-on voltage to the second common word line of the selected memory area to turn on the second transistor of the selected memory area, and reading data stored in the second memory device through the second common bit line of the selected memory area.

### BRIEF DESCRIPTION OF THE DRAWINGS

The accompanying drawings, which form a part hereof, are used to provide a further understanding of the present disclosure. The illustrative embodiments of the present disclosure and descriptions thereof are used to explain the present disclosure, and do not constitute an improper limitation on the present disclosure.

In order to describe the technical solutions of the embodiments of the present disclosure more clearly, the accompanying drawings required for describing the embodiments will be briefly introduced as follows. Apparently, the accompanying drawings, in the following description, illustrate merely some embodiments of the present disclosure, for a person of ordinary skill in the art, other drawings can also be obtained according to these accompanying drawings without making any creative efforts.

FIG. 1 is a schematic circuit diagram of a memory cell according to some embodiments.

FIG. 2 is a schematic circuit diagram of a memory array according to some embodiments.

FIG. 3 is a schematic circuit diagram of reading data from some memory cells in a memory array according to some embodiments.

FIG. 4 is a schematic circuit diagram of erasing data of some memory cells in a memory array according to some embodiments.

FIG. 5 is a schematic circuit diagram of writing data into some memory cells in a memory array according to some embodiments.

FIG. 6 is a schematic circuit diagram of writing data into some memory cells in a memory array according to some other embodiments.

FIG. 7 is a schematic circuit diagram of a memory array in the related art.

FIG. 8 is a schematic flowchart of a data processing method according to some embodiments.

FIG. 9 is a schematic flowchart of a data processing method according to some other embodiments.

### DETAILED DESCRIPTION OF THE EMBODIMENTS

The following describes the implementation of the present disclosure through specific embodiments. Those skilled in the art can easily understand other advantages and effects of the present disclosure from the contents disclosed in this specification. The present disclosure may also be implemented or applied through other different specific embodiments, and the details in this specification may also be modified or changed based on different perspectives and applications without departing from the spirit of the present disclosure. It should be noted that the following embodiments and features therein may be combined with each other without conflict.

While some exemplary embodiments of the present disclosure have been described for the purpose of illustration, it should be understood that the present disclosure may be implemented in other ways not specifically shown in the drawings.

In the description of the embodiments of the present disclosure, the term “and/or” is simply an association relationship for describing associated objects, indicating that there may be three relationships, for example, A and/or B, which can mean: A alone, both A and B, and B alone. In addition, the character “/” herein generally indicates an “or” relationship between the front and back associated objects.

Currently, the electrical performance and reliability of the mainstream flash memory are highly sensitive to the size of the device, and the size of the flash memory is limited by physical laws such as charge discontinuity, so that the storage density and performance of the flash memory are further limited, making it difficult to meet future demand for non-transitory memory.

A resistive random-access memory (RRAM) can be switched between a high resistance state and a low resistance state according to a voltage difference between two electrodes, and has many advantages such as high storage density, fast erase and write speed, easy miniaturization and integration, low power consumption and the like. It has become an emerging non-transitory memory with a great application prospect.

However, the storage density of the memory chip using the resistive random-access memory in the related art is mainly limited by the area and spacing of the transistor. Since the memory device requires a certain write current when performing a write operation, the write current requires the transistor to have a large gate width, which makes it difficult to reduce the area of the transistor.

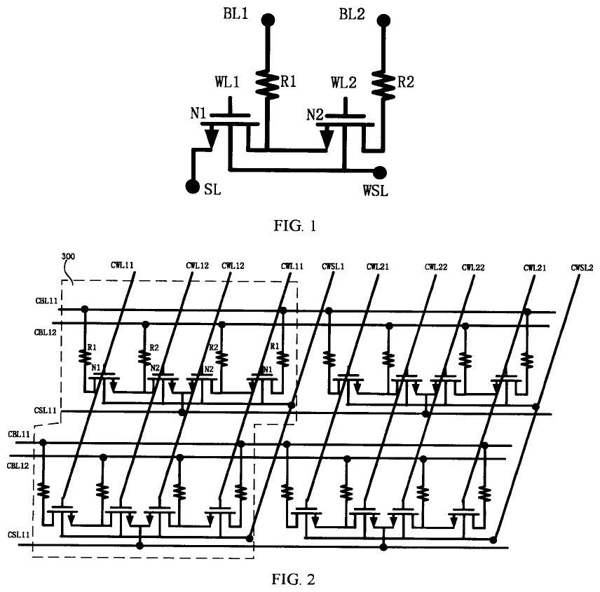

Based on this, referring to FIG. 1, in some embodiments of the present disclosure, a memory cell is provided, including a first transistor N1 and a second transistor N2. The first transistor N1 is configured as follows: a first terminal is configured to be electrically connected to a first bit line BL1 through a first memory device R1, a second terminal is configured to be electrically connected to a source line SL, and a control terminal is configured to be electrically connected to a first word line WL1. The second transistor N2 is configured as follows: a first terminal is configured to be electrically connected to a second bit line BL through a second memory device R2, a second terminal is configured to be electrically connected to the first terminal of the first transistor N1, a control terminal is configured to be electrically connected to a second word line WL, and a substrate of the second transistor N2 is electrically connected to a substrate of the first transistor N1 and is configured to be electrically connected to a write source line WSL.

Exemplarily, referring to FIG. 1, the first memory device R1 and the second memory device R2 each have at least two variable memory states. For example, the first memory device R1 and the second memory device R2 each have a first state of writing first data “0”, a second state of writing second data “1”, a third state of reading the first data “0”, and a fourth state of reading the second data “1”. It can be understood that, in other embodiments of the present disclosure, the data written to or read from the first memory device R1 and the second memory device R2 may be third data different from data “0” and “1”. Exemplarily, the data stored in the first memory device R1 may be determined based on the magnitude of a current read by the first memory device R1 through the first bit line BL1, and the data stored in the second memory device R2 may be determined based on the magnitude of a current read by the second memory device R2 through the second bit line BL2.

Exemplarily, the first memory device R1 is selected from the group consisting of a resistive random-access memory (RRAM), a phase change memory (PCM), and any combination thereof. The second memory device R2 is selected from the group consisting of a resistive random-access memory, a phase change memory, and any combination thereof.

Exemplarily, the first transistor N1 and the second transistor N2 are each a metal-oxide-semiconductor field-effect transistor (MOSFET). For example, the first transistor N1 and the second transistor N2 may be MOSFETs of advanced process nodes.

Taking an example that the first transistor N1 and the second transistor N2 are each the MOSFET, and the first memory device R1 and the second memory device R2 are each the resistive random-access memory, the specific implementation principle of the embodiments of the present disclosure is illustrated below.

Referring to FIG. 1, in some embodiments, the memory cell is configured to perform at least one of the following steps.

Step S110: during an erase/reset state: a write first data signal is provided to the write source line SL, and the first bit line BL1 and the second bit line BL2 are connected to a ground terminal, such that a parasitic PN junction in the substrate of the first transistor N1 and a parasitic PN junction in the substrate of the second transistor N2 are forward biased to write first data to the first memory device R1 and the second memory device R2.

Exemplarily, in the step S110, a write 0 voltage is applied to the write source line WSL corresponding to the memory cell where the memory device to be written is located, and the corresponding two bit lines BL1 and BL2 are grounded (GND). A write 0 voltage is applied to other bit lines, and other ports not mentioned are grounded, so that the parasitic PN junction of the first transistor N1 and the parasitic PN junction of the second transistor N2 in the memory cell corresponding to the write source line WSL are forward biased to write “0” to the first memory device R1 and the second memory device R2.

Step S210: during a write state: a turn-on voltage is applied to the first word line WL1 to turn on the first transistor N1, a write second data signal is provided to the first bit line BL1, and second data is written to the first memory device R1, and/or, a turn-on voltage is applied to the second word line WL2 to turn on the second transistor N2, a write second data signal is provided to the second bit line BL2, and second data is written to the second memory device R2.

Exemplarily, in the step S210, if a write “1” operation needs to be performed on a specified memory cell, after “0” is written to the first memory device R1 and the second memory device R2 in the step S110, the first transistor N1 and the second transistor N2 are turned on by controlling voltages of the first word line WL1 and the second word line WL2, and then a write “1” signal is applied to the first bit line BL1 and the second bit line BL2 of the memory cell, so that “1” is written to the first memory device R1 and the second memory device R2. The bit line corresponding to the memory device that does not need to be written with “1” is grounded, and the other ports not mentioned are grounded.

Exemplarily, since the first transistor N1 is independently controlled through the first word line WL1 and the first bit line BL1, and the second transistor N2 is independently controlled through the second word line WL2 and the second bit line BL2, the first transistor N1 and the second transistor N2 may be controlled one by one, and different data may be written to the first memory device 1 and the second memory device 2, respectively. Alternatively, the first transistor N1 and the second transistor N2 may be controlled simultaneously, and the same data may be written to the first memory device 1 and the second memory device 2 simultaneously.

Step S310: during a read state: a turn-on voltage is applied to the first word line WL1 to turn on the first transistor N1, and data stored in the first memory device R1 is read through the first bit line BL1; and/or, a turn-on voltage is applied to the second word line WL2 to turn on the second transistor N2, and data stored in the second memory device R2 is read through the second bit line BL2.

Exemplarily, in the step S310, when a read operation needs to be performed on a specified memory cell, the first transistor N1 and the second transistor N2 of the memory cell to be read may be first turned on by controlling voltages of the first word line WL1 and the second word line WL2, and then a read voltage signal is applied to the first bit line BL1 and the second bit line BL 2 of the memory cell, and a resistance state of the first memory device R1 is read by reading a current of the first bit line BL1, and a resistance state of the second memory device R2 is read by reading a current of the second bit line BL2.

Exemplarily, since the first transistor N1 is independently controlled through the first word line WL1 and the first bit line BL1, and the second transistor N2 is independently controlled through the second word line WL2 and the second bit line BL2, the first transistor N1 and the second transistor N2 may be controlled one by one, and different data may be read out from the first memory device R1 and the second memory device R2 respectively. Alternatively, the first transistor N1 and the second transistor N2 may be controlled simultaneously, and the same data may be read out from the first memory device R1 and the second memory device R2 simultaneously.

In some embodiments, the present disclosure further provides a memory array, including a plurality of memory areas arranged in a row-column matrix. Each memory area includes a plurality of memory cells in any one of the embodiments as described above. The memory cells in each memory area are configured as follows. Substrates of memory cells in a same memory area are all electrically connected to a same common write source line, memory cells in different memory areas are connected to different common write source lines, respectively, and the common write source lines in different memory areas are insulated from each other. First bit lines of memory cells in a same row in all memory areas are all connected to a same first common bit line, and second bit lines of the memory cells in the same row are all connected to a same second common bit line. First bit lines of memory cells in different rows are connected to different first common bit lines, respectively, and second bit lines of the memory cells in different rows are connected to different second common bit lines, respectively. The first common bit lines of the memory cells in different rows are insulated from each other, the second common bit lines of the memory cells in different rows are insulated from each other, and the first common bit lines and the second common bit lines are insulated from each other.

Control terminals of first transistors of memory cells in a same column in all the memory areas are all connected to a same first common word line, and control terminals of first transistors of memory cells in different columns are connected to different first common word lines, respectively. Control terminals of second transistors of the memory cells in the same column are all connected to a same second common word line, and control terminals of second transistors of the memory cells in different columns are connected to different second common word lines, respectively. The first common word lines of the memory cells in different columns are insulated from each other, the second common word lines of the memory cells in different columns are insulated from each other, and the first common word lines and the second common word lines are insulated from each other.

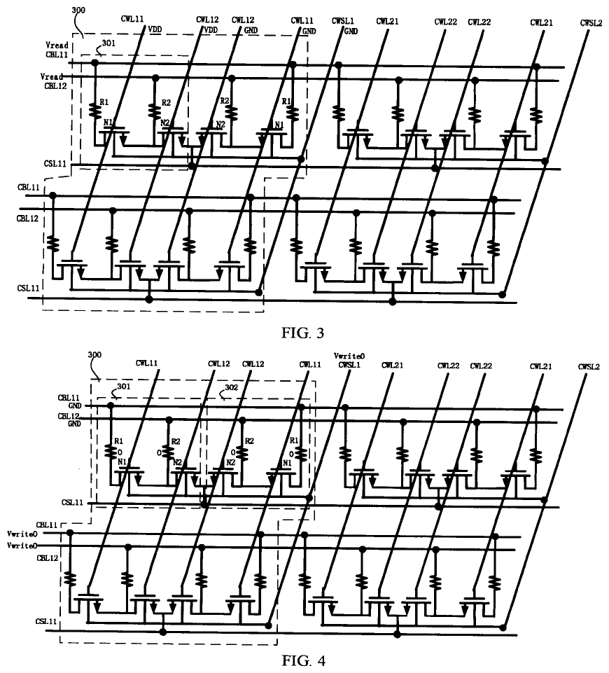

As an example, referring to FIG. 2, a memory array includes a plurality of memory areas 300 arranged in a row-column matrix, and each memory area 300 includes a plurality of memory cells arranged in a row-column matrix. The memory cells in each memory area 300 are all configured as follows. Substrates are all electrically connected to a same common write source line CWSL1. First bit lines of memory cells in a same row are all connected to a same first common bit line CBL11, and first bit lines of memory cells in different rows are connected to different first common bit lines CBL11, respectively. Second bit lines of the memory cells in the same row are all connected to a second common bit line CBL12, and second bit lines of the memory cells in different rows are connected to different second common bit lines CBL12, respectively. The first common bit lines CBL11 of the memory cells in different rows are insulated from each other, and the second common bit lines CBL12 of the memory cells in different rows are insulated from each other. The first common bit lines CBL11 and the second common bit lines CBL12 are insulated from each other. Control terminals of first transistors of memory cells in a same column are all connected to a same first common word line CWL11, and control terminals of first transistors of memory cells in different columns are connected to different first common word lines CWL11, respectively. Control terminals of second transistors of the memory cells in the same column are all connected to a same second common word line CWL12, and control terminals of second transistors of the memory cells in different columns are connected to different second common word lines CWL12, respectively. The first common word lines CWL11 of the memory cells in different columns are insulated from each other, the second common word lines CWL12 of the memory cells in different columns are insulated from each other, and the first common word lines CWL11 and the second common word lines CWL12 are insulated from each other. Memory cells in different memory areas 300 are connected to different common write source lines, and the common write source lines in different memory areas 300 are insulated from each other.

It should be noted that although the memory area 300 in FIG. 2 includes 4 memory cells, it does not constitute a limitation on the quantity of the memory cells included in the memory area 300. In some other embodiments, the memory area 300 may include 2K memory cells, and K is a positive integer.

The following takes reading data stored in the memory cell 301 in the memory area 300 in FIG. 3 as an example to exemplarily describe an implementation principle of the data reading method in the embodiments of the present disclosure.

Referring to FIG. 3, the selected memory cell 301 in the memory area 300 is configured as follows. The common write source line CWSL1 is grounded GND, and the first common word line CWL11 and the second common word line CWL12 are each connected to a DC voltage VDD. A read voltage Vread is provided to the first common bit line CBL11 and the second common bit line CBL12, and the remaining ports are grounded GND. The resistance state of the first memory device R1 in the memory cell 301 can be read through the first common bit line CBL11, and the resistance state of the second memory device R2 in the memory cell 301 can be read through the second common word line CWL12.

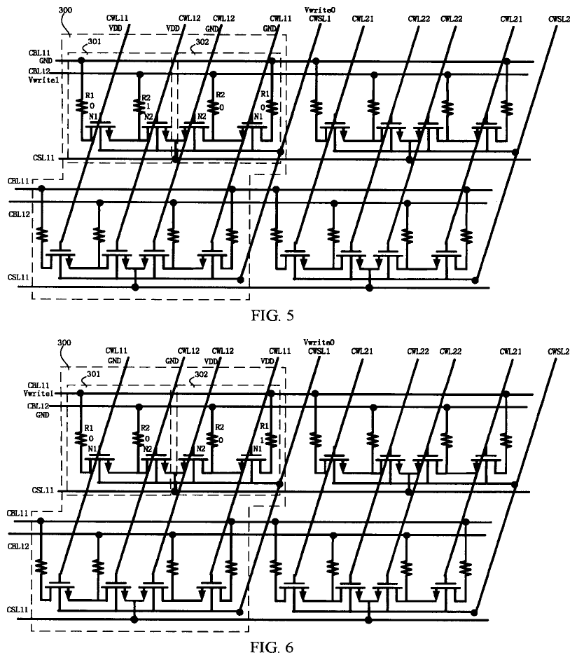

Referring to FIG. 4 to FIG. 5, if “0100” needs to be written to the selected memory cell 301 and the selected memory cell 302 in the memory area 300, “0” needs to be written to the first memory device R1 in the selected memory cell 301, “1” needs to be written to the second memory device R2 in the selected memory cell 301, “0” needs to be written to the first memory device R1 in the selected memory cell 302, and “0” needs to be written to the second memory device R2 in the selected memory cell 301. The following steps may be performed.

Step S101′: during an erase/reset state, a write first data signal V_{write0} is provided to the common write source line CWSL1 of the selected memory area 300, and the first common bit line CBL11 and the second common bit line CBL12 are connected to the ground terminal GND, such that the parasitic PN junction in the substrate of the first transistor N1 of the selected memory cell 301, the parasitic PN junction in the substrate of the second transistor N2 of the selected memory cell 301, the parasitic PN junction in the substrate of the first transistor N1 of the selected memory cell 302, and the parasitic PN junction in the substrate of the second transistor N2 of the selected memory cell 302 are forward biased to write “0” to the first memory device R1 and the second memory device R2 in the selected memory cell 301, and the first memory device R1 and the second memory device R2 in the selected memory cell 302.

Step S201′: after the step S101′ is performed, a turn-on voltage VDD is applied to the second common word line CWL12 of the selected memory cell 301 to turn on the second transistor N2 of the selected memory cell 301, a write “1” signal V_{write1} is applied to the second common word line CWL12 of the selected memory cell 301, and “1” is written to the second memory device R2 of the selected memory cell 301. In this case, the selected memory cell 301 and the selected memory cell 302 are written with 0100.

Referring to FIG. 6, after the step S101′ is performed, a turn-on voltage VDD may be applied to the first common word line CWL11 of the selected memory cell 302, the first transistor N1 of the selected memory cell 302 is turned on, a write “1” signal V_{write1} is applied to the first common bit line CBL11 of the selected memory cell 302, and “1” is written to the first memory device R1 of the selected memory cell 302. In this case, the selected memory cell 301 and the selected memory cell 302 are written with 0001.

In the embodiments of the present disclosure, each memory device may be separately controlled by using a respective independent word line and bit line, so that the memory array can be controlled to be written with any data.

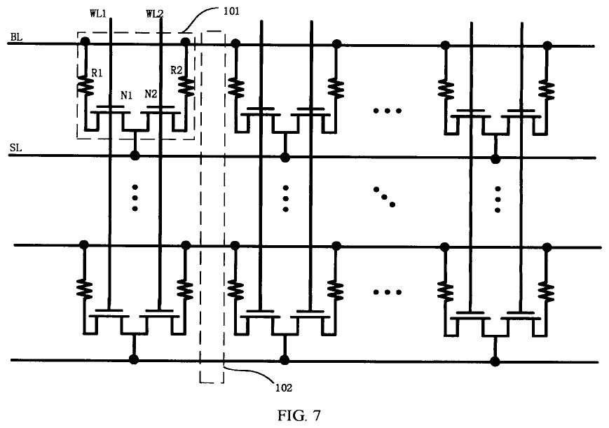

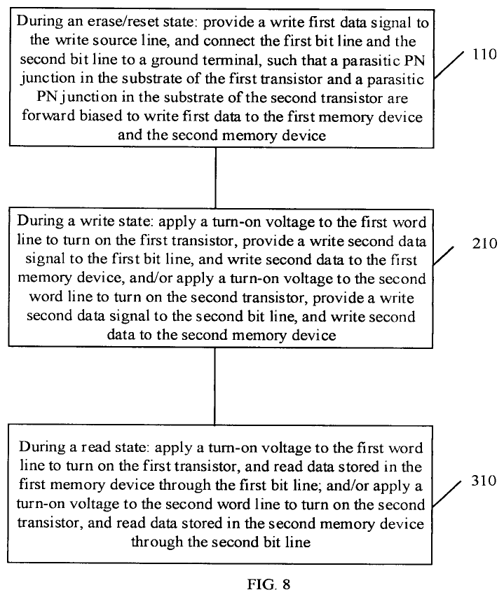

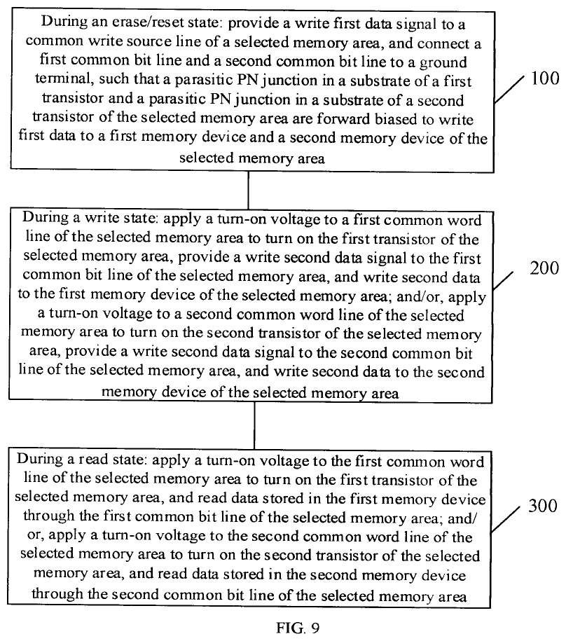

Referring to FIG. 7, in the related art, the transistor in the memory cell 101 is taken as a select transistor. When the transistor is turned on, the memory device can be selected for operation. When the transistor is turned off, the memory device cannot be operated. The memory device N1 or the memory device N2 requires a certain current when performing a write operation, and the current requires that the transistor has a large gate width, so that the area of the transistor is difficult to decrease, resulting in a relatively large volume of the memory cell and a reduced storage density of the memory, and there is a spacing structure 102 in two adjacent columns of memory cells 101, which restricts further decrease of the area of the memory cell.

In comparison, in the memory cell and the memory array provided in the above embodiments of the present disclosure, the parasitic PN junction of the transistor is led out from an independent substrate to achieve a partial write operation of the resistive memory cell, thereby reducing the area of the transistor. In addition, by using a cell design in which transistors are connected in series, the area waste caused by the spacing between transistors is minimized, thereby effectively improving the storage density of the memory array.

In some embodiments, the present disclosure further provides an electronic device, including the memory cell in any one of the above embodiments.

In some embodiments, the present disclosure further provides an electronic device, including the memory array in any one of the above embodiments.

Based on the same inventive concept, embodiments of the present disclosure further provide a data processing method. The implementation solution for solving the problem provided by the method is similar to the implementation solution of the memory cell or the memory array documented above, so the specific limitations in the one or more embodiments of the data processing method provided below may refer to the limitations on the memory cell or the memory array, and details are not described herein again.

In some embodiments, the present disclosure further provides a data processing method, configured to perform data processing (for example, read and/or write data) on the memory cell in any one of the above embodiments. The data processing method includes at least one of the following steps S110 to S310.

In the step S110, during an erase/reset state, a write first data signal is provided to the write source line, and the first bit line and the second bit line are connected to a ground terminal, such that a parasitic PN junction in the substrate of the first transistor and a parasitic PN junction in the substrate of the second transistor are forward biased to write first data to the first memory device and the second memory device.

In the step S210, during a write state, a turn-on voltage is applied to the first word line to turn on the first transistor, a write second data signal is provided to the first bit line, and second data is written to the first memory device; and/or a turn-on voltage is applied to the second word line to turn on the second transistor, a write second data signal is provided to the second bit line, and second data is written to the second memory device.

In the step S310, during a read state, a turn-on voltage is applied to the first word line to turn on the first transistor, and data stored in the first memory device is read out through the first bit line; and/or a turn-on voltage is applied to the second word line to turn on the second transistor, and data stored in the second memory device is read out through the second bit line.

In some embodiments, the present disclosure further provides a data processing method, configured to perform data processing (for example, data reading and/or writing processing) on the memory array in any one of the above embodiments. The data processing method includes at least one of the following steps S100 to S300.

In the step S100, during an erase/reset state, a write first data signal is provided to a common write source line of a selected memory area, and a first common bit line and a second common bit line are connected to a ground terminal, such that a parasitic PN junction in a substrate of a first transistor and a parasitic PN junction in a substrate of a second transistor of the selected memory area are forward biased to write first data to a first memory device and a second memory device of the selected memory area;

In the step S200, during a write state, a turn-on voltage is applied to a first common word line of the selected memory area to turn on the first transistor of the selected memory area, a write second data signal is provided to the first common bit line of the selected memory area, and second data is written to the first memory device of the selected memory area; and/or, a turn-on voltage is applied to a second common word line of the selected memory area to turn on the second transistor of the selected memory area, a write second data signal is provided to the second common bit line of the selected memory area, and second data is written to the second memory device of the selected memory area.

In the step S300, during a read state, a turn-on voltage is applied to the first common word line of the selected memory area to turn on the first transistor of the selected memory area, and data stored in the first memory device is read through the first common bit line of the selected memory area; and/or, a turn-on voltage is applied to the second common word line of the selected memory area to turn on the second transistor of the selected memory area, and data stored in the second memory device is read through the second common bit line of the selected memory area.

In the above data processing method, based on the memory cell and/or the memory array described in the above embodiments, the parasitic PN junction of the transistor is led out from an independent substrate to achieve a partial write operation of the resistive memory cell, thereby reducing the area of the transistor. In addition, by using a cell design in which transistors are connected in series, the area waste caused by the spacing between transistors is minimized, thereby effectively improving the storage density of the memory array.

It should be understood that although the individual steps in the flow charts involved in the embodiments as described above are shown sequentially as indicated by arrows, the steps are not necessarily performed sequentially in the order indicated by the arrows. Unless explicitly stated herein, the execution of these steps is not strictly limited in any order and these steps can be performed in any other order. Moreover, at least some of the steps in the flow charts involved in the embodiments as described above may include multiple sub-steps or multiple stages that are not necessarily performed simultaneously, but may be performed at different moments. The order in which these sub-steps or stages are performed is not necessarily sequential, and these sub-steps or stages may be performed in turn or alternately with at least some of other steps or at least some of sub-steps or stages in other steps.

A person of ordinary skill in the art may understand that implementation of all or part of the processes in the methods of the above embodiments may be completed by instructing the relevant hardware through a computer program. The computer program may be stored in a non-transitory computer-readable storage medium. When the computer program is executed, it may include the processes of the respective methods according to the foregoing embodiments. Any reference to memory, database or other medium used of the embodiments provided in the present disclosure may include at least one of a non-transitory or a transitory memory. The non-transitory memory may include a read-only memory (ROM), a magnetic tape, a floppy disk, a flash memory, an optical memory, a high-density embedded non-transitory memory, a resistive random-access memory (ReRAM), a magneto resistive random-access memory (MRAM), a ferroelectric random-access memory (FRAM), a phase change memory (PCM), or a graphene memory, etc. The transitory memory may include a random-access memory (RAM) or an external cache memory, etc. As an illustration rather than a limitation, the random-access memory may be in various forms, such as a static random-access memory (SRAM) or a dynamic random-access memory (DRAM), etc. The databases involved in the embodiments provided by the present disclosure may include at least one of a relational database and a non-relational database. The non-relational database may include, but is not limited to, a blockchain-based distributed database, etc. The processor involved in the embodiments provided by the present disclosure may be, but is not limited to, a general purpose processor, a central processor, a graphics processor, a digital signal processor, a programmable logic device, a data processing logic device based on quantum computation, and the like.

The technical features in the above embodiments may be combined arbitrarily. For concise description, not all possible combinations of the technical features in the above embodiments are described. However, provided that they do not conflict with each other, all combinations of the technical features are to be considered to be within the scope of protection of the present disclosure.

The above-mentioned embodiments only describe several implementations of the present disclosure, and their description is specific and detailed, but should not be understood as a limitation on the protection scope of the present disclosure. It should be noted that, for a person of ordinary skill in the art, various variations and improvements can be further made without departing from the conception of the present disclosure, and these all fall within the protection scope of the present disclosure. Therefore, the protection scope of the present disclosure should be subject to the appended claims.

What is claimed is:

1. A memory cell, comprising:
a first transistor, a first terminal of the first transistor being configured to be electrically connected to a first bit line through a first memory device, a second terminal of the first transistor being configured to be electrically connected to a source line, a control terminal of the first transistor being configured to be electrically connected to a first word line; and
a second transistor, a first terminal of the second transistor being configured to be electrically connected to a second bit line through a second memory device, a second terminal of the second transistor being configured to be electrically connected to the first terminal of the first transistor, a control terminal of the second transistor being configured to be electrically connected to a second word line, and a substrate of the second transistor is electrically connected to a substrate of the first transistor and is configured to be electrically connected to a write source line.

2. The memory cell of claim 1, wherein the first memory device and the second memory device each have at least two variable memory states.

3. The memory cell of claim 2, wherein the first memory device is selected from the group consisting of a resistive random-access memory, a phase change memory, and any combination thereof; and/or
the second memory device is selected from the group consisting of a resistive random-access memory, a phase change memory, and any combination thereof.

4. The memory cell of claim 1, wherein the first transistor and the second transistor are each a metal-oxide-semiconductor field-effect transistor.

5. The memory cell of claim 1, wherein the memory cell is configured to:
during an erase/reset state: provide a write first data signal to the write source line, and connect the first bit line and the second bit line to a ground terminal, such that a parasitic PN junction in the substrate of the first transistor and a parasitic PN junction in the substrate of the second transistor are turned on to write first data to the first memory device and the second memory device; and
during a write state: apply a turn-on voltage to the first word line to turn on the first transistor, provide a write second data signal to the first bit line, and write second data to the first memory device; and/or, apply a turn-on voltage to the second word line to turn on the second transistor, provide a write second data signal to the second bit line, and write second data to the second memory device.

6. The memory cell of claim 1, wherein the memory cell is configured to:
during a read state: apply a turn-on voltage to the first word line to turn on the first transistor, and read data stored in the first memory device through the first bit line; and/or
apply a turn-on voltage to the second word line to turn on the second transistor, and read data stored in the second memory device through the second bit line.

7. A memory array, comprising a plurality of memory areas arranged in a row-column matrix;
each memory area comprising a plurality of memory cells of claim 1 arranged in a row-column matrix;
wherein the memory cells of each memory area are configured as follows: first bit lines of memory cells in a same row are all connected to a same first common bit line, second bit lines of the memory cells in the same row are all connected to a same second common bit line, first bit lines of memory cells in different rows are connected to different first common bit lines, respectively, and second bit lines of the memory cells in different rows are connected to different second common bit lines, respectively; and
control terminals of first transistors of memory cells in a same column are all connected to a same first common word line, and control terminals of first transistors of memory cells in different columns are connected to different first common word lines, respectively; control terminals of second transistors of the memory cells in the same column are all connected to a same second common word line, and control terminals of second transistors of the memory cells in different columns are connected to different second common word lines, respectively;
wherein substrates of all transistors of memory cells in a same memory area are all electrically connected to a same common write source line, and memory cells in different memory areas are connected to different common write source lines, respectively.

8. The memory array of claim 7, wherein the first memory device and the second memory device in each memory cell each have at least two variable memory states.

9. The memory array of claim 8, wherein the first memory device is selected from the group consisting of a resistive random-access memory, a phase change memory, and any combination thereof; and/or
the second memory device is selected from the group consisting of a resistive random-access memory, a phase change memory, and any combination thereof.

10. The memory array of claim 7, wherein the first transistor and the second transistor are each a metal-oxide-semiconductor field-effect transistor.

11. The memory array of claim 7, where the memory array is configured to:
during an erase/reset state: provide a write first data signal to a common write source line of a selected memory area, and connect a first common bit line and a second common bit line to a ground terminal, such that a parasitic PN junction in a substrate of a first transistor and a parasitic PN junction in a substrate of a second transistor of the selected memory area are forward biased to write first data to a first memory device and a second memory device of the selected memory area;
during a write state: apply a turn-on voltage to a first common word line of the selected memory area to turn on the first transistor of the selected memory area, provide a write second data signal to the first common bit line of the selected memory area, and write second data to the first memory device of the selected memory area; and/or, apply a turn-on voltage to a second common word line of the selected memory area to turn on the second transistor of the selected memory area, provide a write second data signal to the second common bit line of the selected memory area, and write second data to the second memory device of the selected memory area; and/or
during a read state: apply a turn-on voltage to the first common word line of the selected memory area to turn on the first transistor of the selected memory area, and read data stored in the first memory device through the first common bit line of the selected memory area; and/or, apply a turn-on voltage to the second common word line of the selected memory area to turn on the second transistor of the selected memory area, and read data stored in the second memory device through the second common bit line of the selected memory area.

12. An electronic device, comprising the memory cell of claim 1.

13. An electronic device, comprising the memory array of claim 7.

14. A data processing method for performing data processing on the memory cell of claim 1, wherein the data processing method comprises at least one of the following steps:
during an erase/reset state: providing a write first data signal to the write source line, and connecting the first bit line and the second bit line to a ground terminal, such that a parasitic PN junction in the substrate of the first transistor and a parasitic PN junction in the substrate of the second transistor are forward biased to write first data to the first memory device and the second memory device;
during a write state: applying a turn-on voltage to the first word line to turn on the first transistor, providing a write second data signal to the first bit line, and writing second data to the first memory device, and/or applying a turn-on voltage to the second word line to turn on the second transistor, providing a write second data signal to the second bit line, and writing second data to the second memory device; and
during a read state: applying a turn-on voltage to the first word line to turn on the first transistor, and reading data stored in the first memory device through the first bit line; and/or applying a turn-on voltage to the second word line to turn on the second transistor, and reading data stored in the second memory device through the second bit line.

15. A data processing method for performing data processing on the memory array of claim 7, wherein the data processing method comprises at least one of the following steps:
during an erase/reset state: providing a write first data signal to a common write source line of a selected memory area, and connecting a first common bit line and a second common bit line to a ground terminal, such that a parasitic PN junction in a substrate of a first transistor and a parasitic PN junction in a substrate of a second transistor of the selected memory area are forward biased to write first data to a first memory device and a second memory device of the selected memory area;
during a write state: applying a turn-on voltage to a first common word line of the selected memory area to turn on the first transistor of the selected memory area, providing a write second data signal to the first common bit line of the selected memory area, and writing second data to the first memory device of the selected memory area; and/or, applying a turn-on voltage to a second common word line of the selected memory area to turn on the second transistor of the selected memory area, providing a write second data signal to the second common bit line of the selected memory area, and writing second data to the second memory device of the selected memory area; and
during a read state: applying a turn-on voltage to the first common word line of the selected memory area to turn on the first transistor of the selected memory area, and reading data stored in the first memory device through the first common bit line of the selected memory area; and/or, applying a turn-on voltage to the second common word line of the selected memory area to turn on the second transistor of the selected memory area, and reading data stored in the second memory device through the second common bit line of the selected memory area.
